(19) United States
(12) Patent Application Publication
(10) Pub. No.: US 2006/0082986 A1
(43) Pub. Date: Apr. 20, 2006

(54) Housing for memory card

(76) Inventors: Chi Hong Chen, Chu-Dong Town (TW); Chen Wen Chuan, Chu-Dong Town (TW); Kuo-Feng Peng, Chu-Dong Town (TW); Chia Jung Chang, Chu-Dong Town (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/963,498

(22) Filed: Oct. 14, 2004

(51) Int. Cl. H05K 7/14

(52) U.S. Cl. 361/797

(57) ABSTRACT

A memory card includes a base plate on which IC chips are connected and a housing is mounted to the base plate. The housing has at least one recess defined in an underside of the housing and sealed by a top which is in flush with the outside of the housing. At leas tone of the IC chips is accommodated in the recess.

### FIELD OF THE INVENTION

The present invention relates to a memory card including a housing having at least one recess covered by a thinner portion so as to accommodate a chip of regular size on the circuit board.

### BACKGROUND OF THE INVENTION

A conventional memory card 10 used in digital cameras, PDAs, cellular phones or handy computers is shown in FIG. 1 and generally includes a base plate 11 on which various types of IC chips 12 such as Flash chips, or Controller chips are connected in sequence. A process of molding, gluing or sealing is then taken to seal the base plate 11 to form a desired circuit board. An outer housing 13 is then mounted to the combination of the base 11 and the chips 12.

The memory cards has a standard thickness of so that the thickness of the IC chips 12 is limited within a small range and this requires special material and machine to make. A high manufacturing cost is expected and the source for having these IC chips becomes limited. Besides, only 0.2 mm to 0.3 mm of thickness is allowed for the outer housing 13 and the thin outer housing is difficult to be manufactured and suffered by high manufacturing cost.

The present invention intends to provide a housing for a memory card and the housing includes at least one recess defined in an underside thereof and covered by a very thin layer of the material of the housing so that a chip of regular size can be used in the memory card.

### SUMMARY OF THE INVENTION

The present invention relates to a memory card that comprises a base plate and IC chips are connected on the base plate. A housing is mounted to the base plate and includes at least one recess defined in an underside thereof so as to accommodate at least one of the IC chips therein. The at least one recess is sealed by a top which is in flush with a top surface of the housing.

The primary object of the present invention is to provide a housing of a memory card and the housing includes recesses for receiving chips of regular sizes.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is a cross sectional view to show a conventional memory card;

FIG. 2 is an exploded view to show the base plate and the housing of the memory card of the present invention, and

FIG. 3 is a cross sectional view to show the memory card of the present invention.

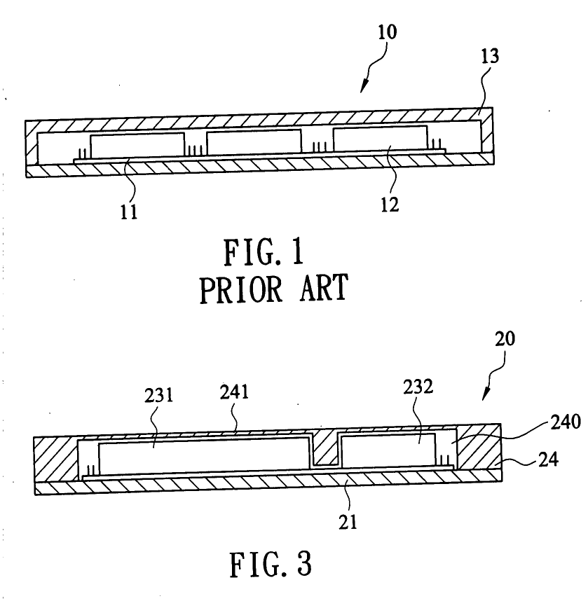

### DETAILED DESCRIPTION OF THE PREFERRED EMBODIMENT

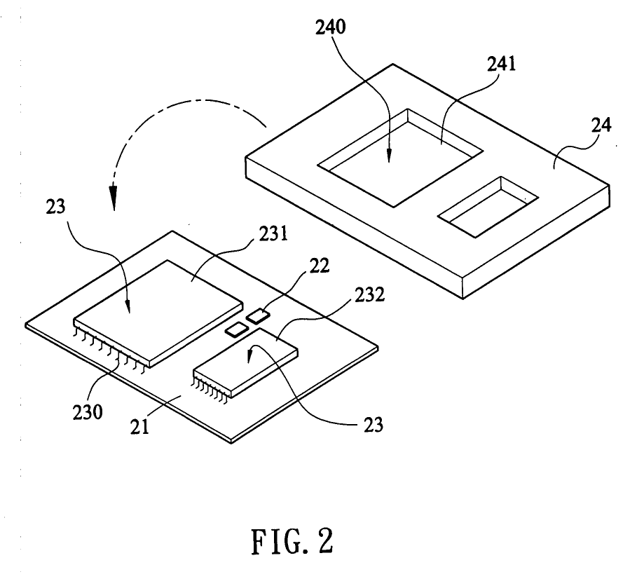

Referring to FIGS. 2 and 3, the memory card 20 of the present invention comprises a base plate 21 on which different types of IC chips 23 such as passive chips 22 and IC chips 23 which include a flash memory 231 and a controller chip 232 are connected in sequence. The flash memory 231 and controller chip 232 are regular sizes which may be 1.0 mm in thickness. The flash memory 231 and controller chip 232 include connection legs 230 extending therefrom and electrically connected to the base plate 21 so as to form a circuit board.

A housing 24 is mounted to the base plate 21 and includes two recesses 240 defined in an underside of the housing 24. The recesses 240 are located corresponding to the flash memory 231 and controller chip 232 of regular sizes. The recesses 240 are sealed by two respective tops 241. The top surface of the top 241 is in flush with the top surface of the housing 24.

By this arrangement, the flash memory 231 and controller chip 232 can be purchased without extra payment for the minimized sizes, so that the cost for the chips can be reduced. The standard thickness of the memory card is 1.4 mm with a plus and minus tolerance of 0.1 mm. Generally, the base plate 21 is 0.3 mm in thickness and the height from the top surface of the base plate 21 to the top surface of the housing 24 is 1.1 mm. The top 241 is less than 0.1 mm so that the thickness of the flash memory 231 and controller chip 232 can be 1.0 mm.

The housing 24 can be made by way of plastic injection so that the number of the recesses 240 can be easily made and the manufacturing cost is affordable.

While we have shown and described the embodiment in accordance with the present invention, it should be clear to those skilled in the art that further embodiments may be made without departing from the scope of the present invention.

What is claimed is:

1. A memory card comprising:
a base plate on which IC chips are connected;
a housing mounted to the base plate and at least one recess defined in an underside of the housing and the at least one recess being sealed by a top, at leas tone of the IC chips being accommodated in the recess.

2. The memory card as claimed in claim 1, wherein the at least one of the IC chips includes connection legs extending therefrom and electrically connected to the base plate.

3. The memory card as claimed in claim 1, wherein the IC chips on the base plate include flash memories and controller chips.

4. The memory card as claimed in claim 1, wherein a top surface of the top is in flush with a top surface of the housing.
